(19) United States
(12) Patent Application Publication
(10) Pub. No.: US 2012/0085573 A1
(43) Pub. Date: Apr. 12, 2012

(54) STACKED STRUCTURE AND METHOD OF MANUFACTURING THE SAME

(75) Inventors: Hitoshi Noguchi, Kobe-shi (JP); Naoki Tanaka, Neyagawa-shi (JP); Tatsuya Nakamura, Osaka-shi (JP)

(73) Assignee: SANYO ELECTRIC CO., LTD., Moriguchi-shi, Osaka (JP)

(21) Appl. No.: 13/377,882

(22) PCT Filed: May 7, 2010
(86) PCT No.: PCT/JP2010/057818

§ 371 Date: Dec. 13, 2011

(30) Foreign Application Priority Data
Jun. 24, 2009 (JP) 2009-149473

(51) Int. Cl. H05K 1/16; H05K 3/10

(52) U.S. Cl. 174/260; 427/97.1

(57) ABSTRACT

A problem to be solved is to suppress deterioration of insulating properties in a stacked structure with a dielectric film formed by powder spraying coating process, and in a method of manufacturing the stacked structure. In a stacked structure according to the present invention, a dielectric layer 3 is provided between a first conductive layer 1 and a second conductive layer 2. The dielectric layer 3 includes an underlying layer 31 formed by applying a dispersion solution containing dielectric particles onto the first conductive layer 1, and a dielectric film 32 formed on the underlying layer 31 by powder spraying coating process. A method of manufacturing the stacked structure according to the present invention includes a dielectric layer forming step of forming the dielectric layer 3 on the first conductive layer 1, and a conductive layer forming step of forming the second conductive layer 2 on the dielectric layer 3. The dielectric layer forming step includes an underlying layer forming step of forming the underlying layer 31 by applying a dispersion solution containing dielectric particles onto the first conductive layer 1, and a dielectric film forming step of forming the dielectric film 32 on the underlying layer 31 by powder spraying coating process.

### TECHNICAL FIELD

The present invention relates to a stacked structure such as a circuit board in which a capacitor circuit is formed, and a capacitor element, and a method of manufacturing the stacked structure.

### BACKGROUND ART

A stacked structure of this type is formed by providing a dielectric film between a first conductive layer and a second conductive layer. The dielectric film is formed on the first conductive layer by using sol-gel process, MOCVD process, sputtering deposition process, or the like.

In order for the dielectric film to become a film in the form of a denser bulk, formation of the dielectric film by spraying dielectric powder onto a surface of the first conductive layer by using various powder spraying coating processes such as powder jet deposition process and aerosol deposition process has been considered in recent years.

### Citation List

### Patent Literature

Patent literature 1: Japanese Patent Application Laid-Open No. 2003-34003

### SUMMARY OF INVENTION

### Problems to be Solved by the Invention

However, if the aforementioned powder spraying coating process is used to form the dielectric film on the surface of the first conductive layer, the surface of the first conductive layer is etched due to collision with the dielectric powder, resulting in a problem in that irregularities are generated in the surface of the first conductive layer as shown in FIG. 7.

Generation of the irregularities in the surface of the first conductive layer makes the thickness of the dielectric film uneven. So, part of the dielectric film may have a considerably reduced thickness. Or, as shown in FIG. 7, part of the first conductive layer may be exposed from a surface of the dielectric film, leading to a fear of deterioration of the insulating properties of the stacked structure.

Patent literature 1 discloses that an underlying layer made of hard particles is formed on a surface of a base material above which a film is to be formed before the film is formed by powder spraying coating process. In patent literature 1 however, the underlying layer is formed by implanting the hard particles into the surface of the base material such that the hard particles dig into the surface, leading to a problem in that irregularities are generated in the surface of the base material.

So, even if the technique of the patent literature 1 is applied to the aforementioned stacked structure, irregularities are still generated in the surface of the first conductive layer, leading to a fear of deterioration of the insulating properties of the stacked structure.

It is therefore an object of the present invention to suppress deterioration of insulating properties in a stacked structure with a dielectric film formed by powder spraying coating process, and in a method of manufacturing the stacked structure.

### Means for Solving Problems

A stacked structure according to the present invention is a stacked structure in which a dielectric layer is provided between a first conductive layer and a second conductive layer. The dielectric layer includes an underlying layer formed by applying a dispersion solution containing dielectric particles onto the first conductive layer, and a dielectric film formed on the underlying layer by powder spraying coating process.

The stacked structure includes stacked structures of various types such as a circuit board with a capacitor circuit formed by providing a dielectric layer between a first conductive layer and a second conductive layer and formed on a substrate, a capacitor element, and a stacked sheet from which a capacitor element can be cut out.

Powder spraying coating process includes various film deposition processes such as aerosol deposition process and powder jet deposition process by which dielectric powder is sprayed to form a dielectric film.

In the aforementioned stacked structure, the underlying layer is formed on a surface of the first conductive layer above which the dielectric film is to be formed. Thus, dielectric powder sprayed by powder spraying coating process collides with the underlying layer, so the surface of the first conductive layer is protected from collision with the dielectric powder by the underlying layer. This prevents generation of irregularities in the surface of the first conductive layer, so the insulating properties of the stacked structure are unlikely to be damaged.

In addition, in the aforementioned stacked structure, the underlying layer is made of dielectric particles. Thus, the dielectric properties of the dielectric layer composed of the underlying layer and the dielectric film are unlikely to be deteriorated.

In a specific formation of the aforementioned stacked structure, the dielectric particles are made of a material having the same main component as that of a dielectric material constituting the dielectric film.

This specific formation makes a difference in coefficient of thermal expansion between the underlying layer and the dielectric film smaller, thereby suppressing an internal defect to be generated by thermal expansion. As a result, the quality of the stacked structure is maintained at a high level.

In a different specific formation of the aforementioned stacked structure, the dispersion solution is prepared by adding dielectric particles and a dispersant to a solvent without using a binder. Use of the binderless dispersion solution does not involve a binder to be present between the dielectric particles in the underlying layer formed by applying the dispersion solution onto the first conductive layer. This flocculates the dielectric particles more densely to enhance the dielectric properties of the dielectric layer.

In a still different specific formation of the aforementioned stacked structure, the dispersion solution is prepared by using sol-gel process. The dielectric particles are monodispersed as primary particles in the dispersion solution prepared by sol-gel process. Thus, the underlying layer formed by applying the dispersion solution onto the first conductive layer has high-level surface smoothness, and has a uniform thickness over the entire surface of the first conductive layer. So, even if irregularities are generated in a surface of the underlying layer as a result of etching of the surface during formation of the dielectric film, the first conductive layer is unlikely to be exposed from the surface of the underlying layer. As a result, the surface of the first conductive layer is protected easily by the underlying layer.

A method of manufacturing a stacked structure according to the present invention is a method of manufacturing a stacked structure in which a dielectric layer is provided between a first conductive layer and a second conductive layer. The method includes a dielectric layer forming step of forming the dielectric layer on the first conductive layer, and a conductive layer forming step of forming the second conductive layer on the dielectric layer.

Here, the dielectric layer forming step includes an underlying layer forming step of forming an underlying layer by applying a dispersion solution containing dielectric particles onto the first conductive layer, and a dielectric film forming step of forming a dielectric film on the underlying layer by powder spraying coating process.

In a specific formation of the aforementioned manufacturing method, the dispersion solution used in the underlying layer forming step contains dielectric particles that are made of a material having the same main component as that of a dielectric material constituting the dielectric film.

### Effect of the Invention

In the stacked structure and the method of manufacturing the stacked structure according to the present invention, the dielectric film is formed by using powder spraying coating process, and in the meantime, the insulating properties of the stacked structure are unlikely to be deteriorated.

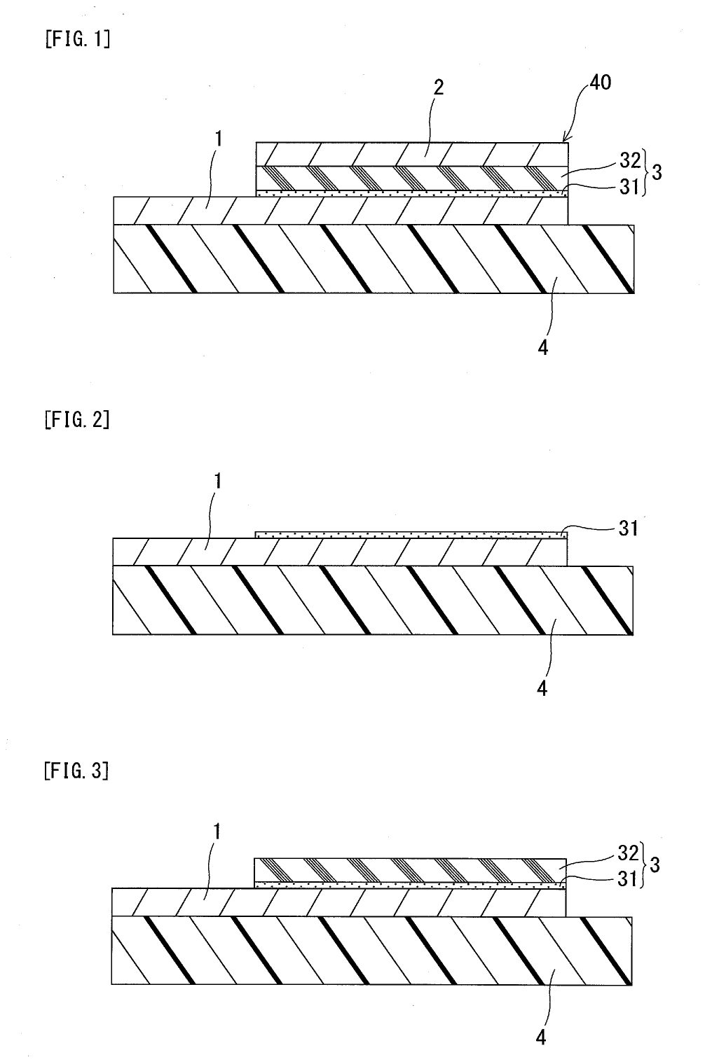

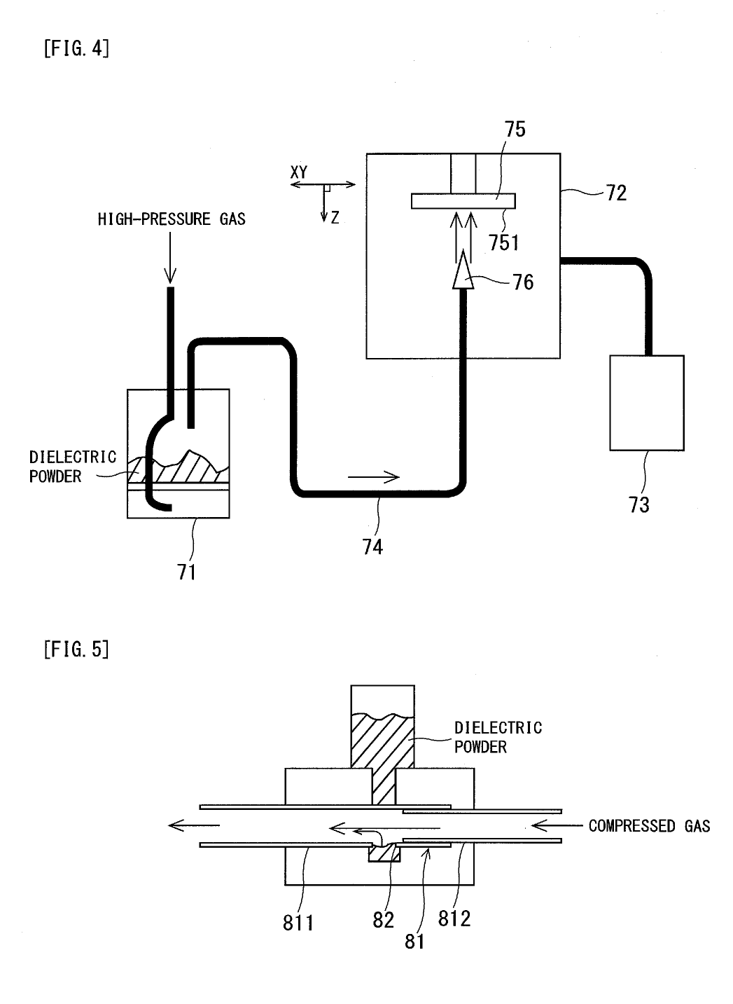

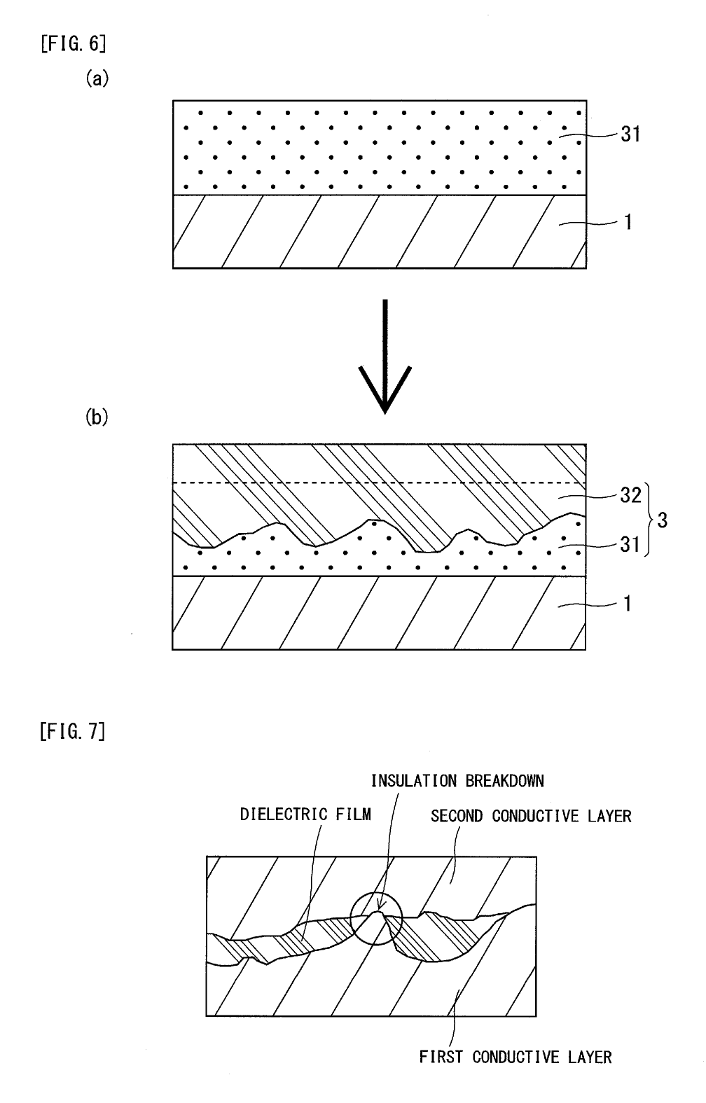

### BRIEF DESCRIPTION OF DRAWINGS

[FIG. 1] FIG. 1 is a sectional view showing a circuit board of an embodiment according to the present invention.

[FIG. 2] FIG. 2 is a sectional view used to explain an underlying layer forming step that is one of steps of manufacturing the circuit board.

[FIG. 3] FIG. 3 is a sectional view used to explain a dielectric film forming step that is one of the steps of manufacturing the circuit board.

[FIG. 4] FIG. 4 is a view showing a film deposition unit used in aerosol deposition process.

[FIG. 5] FIG. 5 is a sectional view showing a spraying unit used in powder jet deposition process.

[FIG. 6] FIGS. 6(a) is a sectional view showing an underlying layer in an enlarged manner after execution of the underlying layer forming step, and FIG. 6(b) is a sectional view showing the underlying layer in an enlarged manner after execution of the dielectric film forming step.

[FIG. 7] FIG. 7 is a sectional view showing the condition of a surface of a first conductive layer on which a dielectric film is formed by powder spraying coating process.

### EMBODIMENTS FOR CARRYING OUT INVENTION

In an embodiment described in detail below by referring to drawings, the present invention is carried out in a circuit board in which a capacitor circuit is formed.

As shown in FIG. 1, the circuit board according to the embodiment of the present invention is a stacked structure with a capacitor circuit (40) formed on a substrate (4). The capacitor circuit (40) is formed by providing a dielectric layer (3) between a first conductive layer (1) and a second conductive layer (2).

The first conductive layer (1) is metallic foil provided on the first substrate (4), and is made of metal such as copper (Cu), nickel (Ni), cobalt (Co), gold (Au), and platinum (Pt). The first conductive layer (1) may be formed on the substrate (4) by using sputtering deposition process, plating process, screen printing process, or the like.

The dielectric layer (3) is composed of an underlying layer (31) formed on the first conductive layer (1), and a dielectric film (32) formed on the underlying layer (31).

The underlying layer (31) is formed by applying a dispersion solution with dielectric particles mainly containing barium titanate (BaTiO3) onto the first conductive layer (1). The dispersion solution is prepared by adding dielectric particles and a dispersant to a solvent without using a binder, and the preparation thereof is realized by using sol-gel process. The dielectric particles in the dispersion solution are nanoparticles having an average particle diameter of 50 nm or smaller. The underlying layer (31) is a thin film formed by flocculation of the dielectric particles as a result of drying of the dispersion solution applied on the first conductive layer (1).

The dielectric film (32) is formed by applying dielectric powder mainly containing barium titanate (BaTiO3) onto a surface of the underlying layer (31) by powder spraying coating process. Details of powder spraying coating process are described later.

In the present embodiment, a dielectric material mainly containing barium titanate (BaTiO3) is used as the dielectric particles constituting the underlying layer (31) and the dielectric film (32). However, the present invention is not intended to be limited to this, but the present invention may use various dielectric materials mainly containing lithium niobate (LiNbO3), lithium borate (Li2B4O7), lead zirconate titanate (PbZrTiO3), strontium titanate (SrTiO3), lead lanthanum zirconate titanate (PbLaZrTiO3), lithium tantalite (LiTaO3), zinc oxide (ZnO), and tantalum oxide (Ta2O5). Dielectric materials having different main components may be used as the dielectric particles constituting the underlying layer (31) and the dielectric film (32).

The dielectric particles constituting the underlying layer (31) and the dielectric film (32) may contain an additive intended to enhance dielectric properties, insulating properties, strength, and the like.

The second conductive layer (2) is a metal film formed on the dielectric layer (3) by using sputtering deposition process, plating process, screen printing process, or the like. Or, the second conductive layer (2) is metallic foil provided on the dielectric layer (3). Like the first conductive layer (1), the second conductive layer (2) is made of metal such as copper (Cu), nickel (Ni), cobalt (Co), gold (Au), and platinum (Pt).

A method of manufacturing the aforementioned circuit board is descried next. In this manufacturing method, a dielectric layer forming step of forming the dielectric layer (3) on the first conductive layer (1), and a conductive layer forming step of forming the second conductive layer (2) on the dielectric layer (3), are performed in this order.

Further, the dielectric layer forming step includes an underlying layer forming step of forming the underlying layer (31) on the first conductive layer (1) as shown in FIG. 2, and a dielectric film forming step of forming the dielectric film (32) on the underlying layer (31) as shown in FIG. 3.

In the underlying layer forming step, the underlying layer (31) is formed by applying a dispersion solution with dielectric particles mainly containing barium titanate (BaTiO3) onto the first conductive layer (1), and by drying the dispersion solution. At this time, the underlying layer (31) is formed so as to have a thickness greater than the thickness thereof to be etched in the dielectric film forming step described later.

The dispersion solution used in the underlying layer forming step is prepared by adding dielectric particles and a dispersant to a solvent without using a binder, and the preparation thereof is realized by using sol-gel process. The dielectric particles in the dispersion solution are nanoparticles having an average particle diameter of 50 nm or smaller.

The dispersion solution is applied by using wet coating process such as dip coating process and spin coating process.

In the dielectric film forming step, the dielectric film (32) is formed on the underlying layer (31) by using powder spraying coating process. Powder spraying coating process includes various film deposition processes such as aerosol deposition process and powder jet deposition process by which dielectric powder is sprayed to form a dielectric film.

Aerosol deposition process is a film deposition process performed by using a film deposition unit shown in FIG. 4 and in which dielectric powder is formed into an aerosol, and the powder is sprayed onto a surface on which a dielectric film is to be formed, thereby forming the dielectric film.

As shown in FIG. 4, the film deposition unit has a structure where an aerosol generator (71) in which dielectric powder is agitated and mixed with high-pressure gas to be formed into an aerosol, and a film deposition chamber (72) capable of keeping the vacuum state inside with a vacuum pump (73), are connected through a narrow transfer tube (74). The inside of the film deposition chamber (72) is kept in vacuum during film deposition. So, a difference in pressure is generated between space inside the aerosol generator (71) into which the high-pressure gas flows (high-pressure space), and space inside the film deposition chamber (72) (low-pressure space). As a result, the dielectric powder formed into an aerosol in the aerosol generator (71) is caused to flow toward the film deposition chamber (72) through the transfer tube (74).

A stage (75) to hold a target object with a surface on which a dielectric film is to be foamed is placed inside the film deposition chamber (72). The stage (75) has a structure that allows translational movement in XY plane parallel to a placement surface (751) on which the target object is placed, translational movement in the direction of Z axis perpendicular to the XY plane, and rotation about the Z axis.

One end of the transfer tube (74) is placed in the film deposition chamber (72). A nozzle (76) in the form of a slit is attached to this end such that a tip end thereof is pointed toward the placement surface (751) of the stage (75). Further, the nozzle (76) has such a shape that allows the speed of discharge of the dielectric powder through one end of the transfer tube (74) to be increased to about 100 m/sec.

Thus, the dielectric powder discharged at a high speed through the tip end of the nozzle (76) is sprayed onto the surface of the target object on the stage (75).

Powder jet deposition process is a film deposition process performed by using a spraying unit shown in FIG. 5 and in which dielectric powder is sprayed onto a surface on which a dielectric film is to be formed, thereby forming the dielectric film.

As shown in FIG. 5, the spraying unit includes a stepped nozzle (81) with two regions (811) and (812) of different inner diameters. The nozzle (81) is provided with a through hole (82) formed in the first region (811) of a large inner diameter and at a position near the second region (812) of a smaller inner diameter, and through which dielectric powder is supplied.

So, if compressed gas is caused to flow in the nozzle (81) from the second region (812) toward the first region (811), a negative pressure is generated at a position near an outlet of the second region (812) at which the inner diameter changes. This negative pressure sucks dielectric powder into the nozzle (81), so the dielectric powder sucked in is discharged at a high speed trough a tip end of the nozzle (81) together with the compressed gas.

Like in aerosol deposition process (see FIG. 4), the discharged dielectric powder is sprayed onto a surface of a target object placed on the stage (75).

In the present embodiment, for formation of the dielectric film (32) on the underlying layer (31) by using various powder spraying coating processes such as aerosol deposition process and powder jet deposition process, dielectric powder of barium titanate (BaTiO3) having a particle diameter of about 1 μm is sprayed onto a surface of the underlying layer (31).

The dielectric powder sprayed on the surface of the underlying layer (31) collides with the surface of the underlying layer (31) or with different dielectric powder to be pulverized, and is then deposited on the underlying layer (31). As a result, the dielectric film (32) is formed on the underlying layer (31). So, the dielectric film (32) becomes a film in the form of a dense bulk if it is formed by powder spraying coating process.

As a result, the underlying layer (31) formed in the underlying layer forming step, and the dielectric film (32) formed in the dielectric film forming step, constitute the dielectric layer (3).

In the conductive layer forming step, a metal film is provided by using sputtering deposition process, plating process, screen printing process, or the like on the dielectric film (32) formed in the dielectric film forming step, or metallic foil is provided on the dielectric film (32), thereby forming the second conductive layer (2). As a result, formation of the circuit board with the substrate (4) and the capacitor circuit (40) formed on the substrate (4) is completed as shown in FIG. 1.

In the circuit board manufactured in the aforementioned manner, the underlying layer (31) is formed on a surface of the first conductive layer (1) above which the dielectric film (32) is to be formed. Thus, dielectric powder sprayed by powder spraying coating process collides with the underlying layer (31), so the surface of the first conductive layer (1) is protected from collision with the dielectric powder by the underlying layer (31). This prevents generation of irregularities in the surface of the first conductive layer (1), so insulation between the first conductive layer (1) and the second conductive layer (2) is unlikely to be broken. To be specific, deterioration of the insulating properties of the capacitor circuit (40) is suppressed in the circuit board.

Further, the underlying layer (31) is made of dielectric particles in the aforementioned circuit board. Thus, the dielectric properties of the dielectric layer (3) composed of the underlying layer (31) and the dielectric film (32) are unlikely to be deteriorated.

In addition, in the aforementioned circuit board, the underlying layer (31) is made of a material having the same main component as that of the dielectric material constituting the dielectric film (32). To be specific, the underlying layer (31) is made of a material mainly containing barium titanate (BaTiO3). This makes a difference in coefficient of thermal expansion between the underlying layer (31) and the dielectric film (32) smaller, thereby suppressing an internal defect to be generated by thermal expansion. As a result, the quality of the circuit board is maintained at a high level.

Still further, in the aforementioned circuit board, the dispersion solution used for forming the underlying layer (31) is prepared by adding dielectric particles and a dispersant to a solvent without using a binder. Use of the binderless dispersion solution does not involve a binder to be present between the dielectric particles in the underlying layer (31) formed by applying the dispersion solution onto the first conductive layer (1). This flocculates the dielectric particles more densely to enhance the dielectric properties of the dielectric layer (3).

The dispersion solution used for forming the underlying layer (31) is prepared by using sol-gel process. The dielectric particles are monodispersed as primary particles in the dispersion solution prepared by sol-gel process. Thus, the underlying layer (31) formed by applying the dispersion solution onto the first conductive layer (1) has high-level surface smoothness as shown in FIG. 6(a), and has a uniform thickness over the entire surface of the first conductive layer (1).

So, even if irregularities are generated in a surface of the underlying layer (31) as a result of etching of the surface during formation of the dielectric film (32) as shown in FIG. 6(b), the first conductive layer (1) is unlikely to be exposed from the surface of the underlying layer (31). As a result, the surface of the first conductive layer (1) is protected easily by the underlying layer (31).

The structure of each part of the present invention is not limited to that shown in the embodiment described above. Various modifications can be devised without departing from the technical scope recited in claims. By way of example, the aforementioned elements employed in a circuit board in which a capacitor circuit is formed are also applicable in a capacitor element, or a stacked sheet from which a capacitor element can be cut out. The capacitor element and the stacked sheet may not have an element corresponding to the substrate (4) as part of the aforementioned circuit board.

### REFERENCE SIGNS LIST

(1) First conductive layer

(2) Second conductive layer

(3) Dielectric layer

(31) Underlying layer

(32) Dielectric film

(4) Substrate

1. A stacked structure comprising:
a first conductive layer;
an underlying layer formed by applying a dispersion solution containing dielectric particles onto the first conductive layer;
a dielectric film formed on the underlying layer by powder spraying coating process; and
a second conductive layer formed on the dielectric film.

2. The stacked structure according to claim 1, wherein the dielectric particles are made of a material having the same main component as that of a dielectric material constituting the dielectric film.

3. The stacked structure according to claim 1, wherein the dispersion solution is prepared by adding dielectric particles and a dispersant to a solvent without using a binder.

4. The stacked structure according to claim 1, wherein the dispersion solution is prepared by using sol-gel process.

5. A method of manufacturing a stacked structure in which a dielectric layer is provided between a first conductive layer and a second conductive layer, the method comprising the steps of:
(a) forming step of forming an underlying layer by applying a dispersion solution containing dielectric particles onto the first conductive layer;
(b) forming a dielectric film on the underlying layer by powder spraying coating process; and
(c) forming the second conductive layer on the dielectric film.

6. The method of manufacturing a stacked structure according to claim 5, wherein the dispersion solution used in the step (a) contains dielectric particles that are made of a material having the same main component as that of a dielectric material constituting the dielectric film.
